(19) United States
(12) Patent Application Publication
(10) Pub. No.: US 2024/0014346 A1
(43) Pub. Date: Jan. 11, 2024

(54) TRANSFER SUBSTRATE USED IN MANUFACTURE OF DISPLAY DEVICE, DISPLAY DEVICE, AND MANUFACTURING METHOD FOR DISPLAY DEVICE

(71) Applicant: LG ELECTRONICS INC., Seoul (KR)

(72) Inventors: Yonghan LEE, Seoul (KR); Yoonyoung CHOI, Seoul (KR); Hwanjoon CHOI, Seoul (KR)

(73) Assignee: LG ELECTRONICS INC., Seoul (KR)

(21) Appl. No.: 18/246,125

(22) PCT Filed: Sep. 24, 2020
(86) PCT No.: PCT/KR2020/012917

§ 371 Date: Mar. 21, 2023

(51) Int. Cl. H01L 33/08; H01L 33/44; H01L 33/00; H01L 33/06; H01L 27/15; H01L 25/075

(52) U.S. Cl. CPC H01L 33/08; H01L 33/44; H01L 33/007; H01L 33/0095; H01L 33/0075; H01L 33/06; H01L 27/156; H01L 25/0753; H01L 2933/0025; H01L 33/0093

(57) ABSTRACT

The present invention is applicable to display device-related technical fields and may provide a transfer substrate in which multiple semiconductor light-emitting elements of a first color and a light conversion layer formed on at least a portion of the semiconductor light-emitting elements to convert the first color into a second color or a third color are formed, the transfer substrate comprising: multiple unit pixels including one light-emitting element among the multiple semiconductor light-emitting elements; and a pixel including at least one of the multiple unit pixels, wherein the pixel includes a first pixel and a second pixel adjacent to each other and the light conversion layer of the unit pixel disposed at a position adjacent to the first pixel and the second pixel includes a light-emitting element which converts the first color into the same color.

### TECHNICAL FIELD

The present disclosure is applicable to a display device-related technical field, and relates to, for example, a method for manufacturing a display device using light emitting diodes (LEDs) and a transfer substrate used for manufacturing the display device.

### BACKGROUND ART

Recently, in order to implement large-sized, thin, and flexible displays in the field of display technology, liquid crystal displays (LCDs), organic light emitting diode (OLED) displays, micro-LED displays, etc. have been developed and rapidly come into widespread use.

A micro-LED is a semiconductor light emitting device (micro-LED) having a diameter or cross-sectional area of 100 microns or less. When the micro-LED is applied to a display, light is not absorbed by a separate polarizer and the micro-LED can self-emit light, so that the micro-LED can provide very high efficiency.

However, micro-LEDs have difficulties in satisfying exact alignment conditions in a process of transferring the micro-LEDs. When using RGB light emitting diodes (LEDs), each of the red LED, the green LED, and the blue LED should be transferred so that the difficulty of the transfer process of the RGB LEDs unavoidably increases.

### DISCLOSURE

### Technical Problem

An object of the present disclosure is to provide a transfer substrate used for manufacturing a display device capable of increasing the efficiency of a transfer process, a display device, and a method for manufacturing the display device.

Furthermore, according to another object of the present disclosure, there are additional problems not mentioned herein. Those skilled in the art will appreciate such problems through the whole of the specification and drawings.

### Technical Solutions

In accordance with an aspect of the present disclosure, a transfer substrate may include a plurality of semiconductor light emitting elements having a first color, and a light conversion layer formed on at least a portion of the semiconductor light emitting element to convert the first color into a second or third color. The transfer substrate may include a plurality of unit pixels including one light emitting element among the plurality of semiconductor light emitting elements, and at least one pixel including at least one of the plurality of unit pixels. The at least one pixel may include a first pixel and a second pixel. The light conversion layer of the unit pixel disposed at a position neighboring the first pixel and the second pixel may include a light emitting element for converting the first color into the same color as the first color.

In accordance with another aspect of the present disclosure, a method for manufacturing a display device may include: forming a plurality of unit pixels each including a semiconductor light emitting element of a first color; forming an array of semiconductor light emitting elements each including the plurality of unit pixels; disposing a barrier on one surface of some semiconductor light emitting elements among the semiconductor light emitting element array such that the barrier includes some of the plurality of semiconductor light emitting elements; and forming a light conversion layer configured to convert the first color into a second or third color. A method for forming the semiconductor light emitting element array may include disposing at least one semiconductor light emitting element to be converted into the second color at a position neighboring a semiconductor light emitting element to be converted into the second color, and disposing at least one semiconductor light emitting element to be converted into the third color at a position adjacent to a semiconductor light emitting element to be converted into the third color.

In accordance with another aspect of the present disclosure, a display device may include: a semiconductor light emitting element configured to display light of a first color; a light conversion layer disposed inward from one surface of the semiconductor light emitting element, and formed in a nanopore structure to convert the first color into a second color different from the first color; and a protective layer stacked on one surface of the semiconductor light emitting element to cover the light conversion layer, wherein the protective layer is configured in a manner that one surface thereof facing one surface of the semiconductor light emitting element is formed to be rougher than the outer surface contacting one surface of the semiconductor light emitting element.

### Advantageous Effects

According to the transfer substrate used for manufacturing the display device of the present disclosure, the display device, and the method for manufacturing the display device, all of the RGB light emitting diodes (LEDs) are included on one transfer substrate, and all of the red LED, the green LED, and the blue LED can be transferred through only one transfer process, thereby increasing the transfer efficiency due to the reduction of the number of transfer actions.

According to the transfer substrate used for manufacturing the display device of the present disclosure, the display device, and the method for manufacturing the display device, pixels located adjacent to each other on a transfer substrate are arranged in a point-symmetrical format, resulting in increased efficiency of a manufacturing process.

According to the transfer substrate used for manufacturing the display device of the present disclosure, the display device, and the method for manufacturing the display device, pixels are formed in a single chip structure and the display device is configured to convert a color signal into another color signal during operation thereof, such that the fabrication change caused by rotation of the chip during a self-assembly process of the single chip does not occur, resulting in increased efficiency of the manufacturing process.

According to the transfer substrate used for manufacturing the display device of the present disclosure, the display device, and the method for manufacturing the display device, pixels disposed on the transfer substrate may include two or more donors, and the pixels can thus be applied to any structure of a vertical light emitting element and a horizontal light emitting element.

According to the transfer substrate used for manufacturing the display device of the present disclosure, the display device, and the method for manufacturing the display device, additional technical effects not specifically mentioned herein are also provided by the structure and method thereof. A person skilled in the art to which the present disclosure pertains can understand through the whole of the specification and drawings.

### DESCRIPTION OF DRAWINGS

FIG. 1 is a conceptual diagram illustrating an embodiment of a display device using a semiconductor light emitting element according to the present disclosure.

FIG. 2 is a partially enlarged diagram showing a part A shown in FIG. 1.

FIGS. 3A and 3B are cross-sectional diagrams taken along the cutting lines B-B and C-C in FIG. 2.

FIG. 4 is a conceptual diagram illustrating the flip-chip type semiconductor light emitting element of FIG. 3.

FIGS. 5A to 5C are conceptual diagrams illustrating various examples of color implementation with respect to a flip-chip type semiconductor light emitting element.

FIG. 6 shows cross-sectional views of a method of fabricating a display device using a semiconductor light emitting element according to the present disclosure.

FIG. 7 is a perspective diagram of a display device using a semiconductor light emitting element according to another embodiment of the present disclosure.

FIG. 8 is a cross-sectional diagram taken along a cutting line D-D shown in FIG. 8.

FIG. 9 is a conceptual diagram showing a vertical type semiconductor light emitting element shown in FIG. 8.

FIG. 10 is a top view schematically illustrating a first arrangement of pixels in a transfer substrate according to an embodiment of the present disclosure.

FIG. 11 is a schematic diagram illustrating a structure for transferring a transfer substrate to which a first arrangement of pixels is applied onto a wiring substrate.

FIG. 12 is a top view illustrating an example case in which unit pixels are applied to a single chip in a transfer substrate according to an embodiment of the present disclosure.

FIG. 13 is a top view illustrating a second arrangement of pixels in a transfer substrate according to an embodiment of the present disclosure.

FIGS. 14(a) to 14(e) are cross-sectional views illustrating examples of a method for manufacturing the display device using semiconductor light emitting elements according to embodiments of the present disclosure.

FIG. 15 is a schematic cross-sectional view illustrating semiconductor light emitting elements according to an embodiment of the present disclosure.

FIGS. 16(a) to 16(g) are cross-sectional views illustrating examples of a method for manufacturing the display device using semiconductor light emitting elements according to embodiments of the present disclosure.

FIG. 17 is a schematic cross-sectional view illustrating a semiconductor light emitting element according to an embodiment of the present disclosure.

FIG. 18 is a cross-sectional view illustrating a display device manufactured according to embodiments of the present disclosure.

FIG. 19 is a cross-sectional view illustrating a display device manufactured according to embodiments of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting element mentioned in this specification is a concept including an LED, a micro LED, and the like.

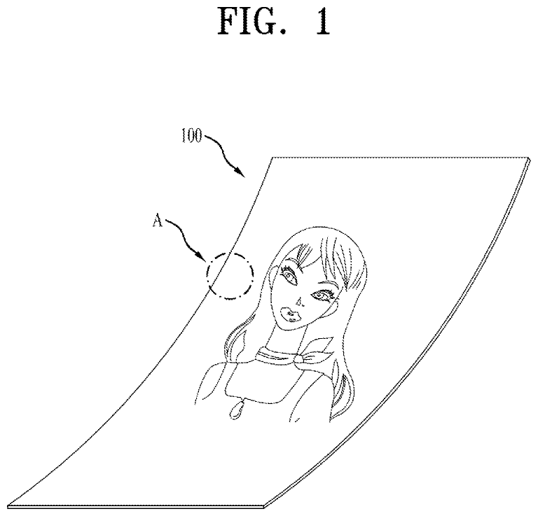

FIG. 1 is a conceptual view illustrating an embodiment of a display device using a semiconductor light emitting element according to the present disclosure.

As shown in FIG. 1, information processed by a controller (not shown) of a display device 100 may be displayed using a flexible display.

The flexible display may include, for example, a display that can be warped, bent, twisted, folded, or rolled by external force.

Furthermore, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first sate is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light emitting element. In the present disclosure, a light emitting diode (LED) is exemplified as a type of the semiconductor light emitting element configured to convert electric current into light. The LED may be formed in a small size, and may thus serve as a unit pixel even in the second state.

Hereinafter, a flexible display implemented using the LED will be described in more detail with reference to the drawings.

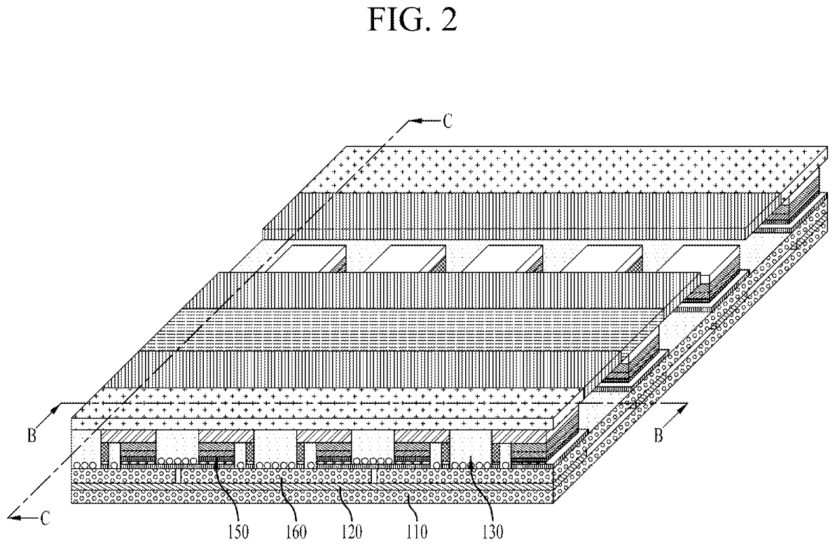

FIG. 2 is a partially enlarged view showing part A of FIG. 1.

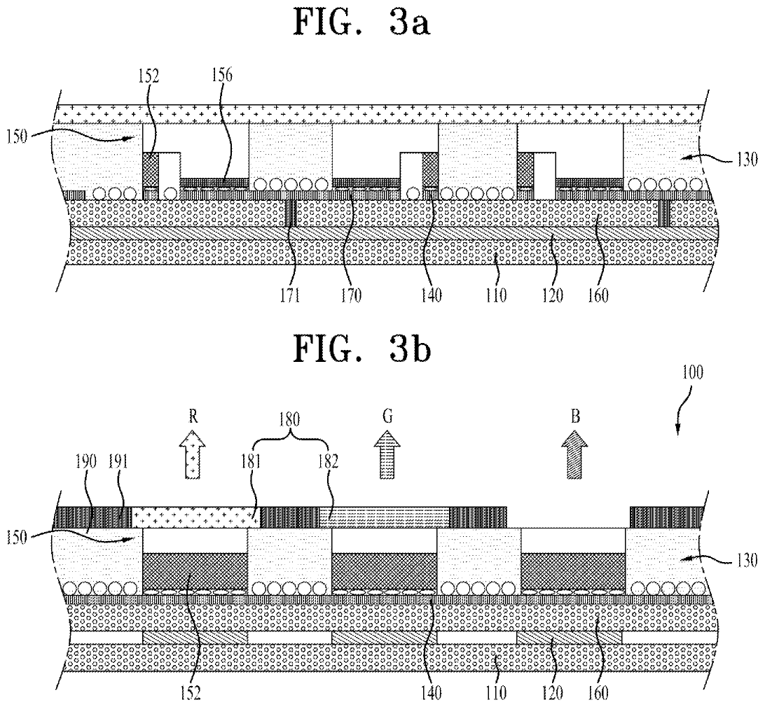

FIGS. 3A and 3B are cross-sectional views taken along lines B-B and C-C in FIG. 2.

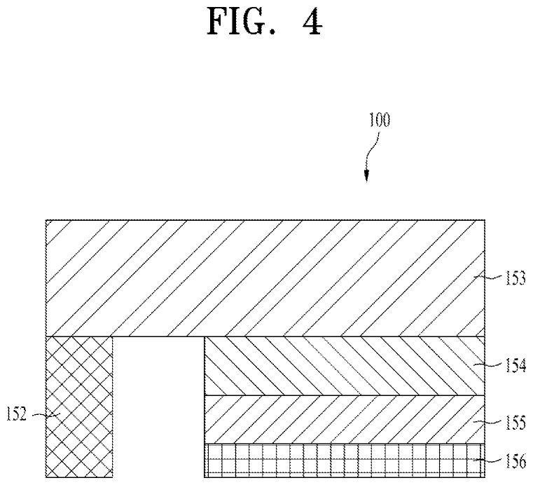

FIG. 4 is a conceptual view illustrating the flip-chip type semiconductor light emitting element of FIG. 3.

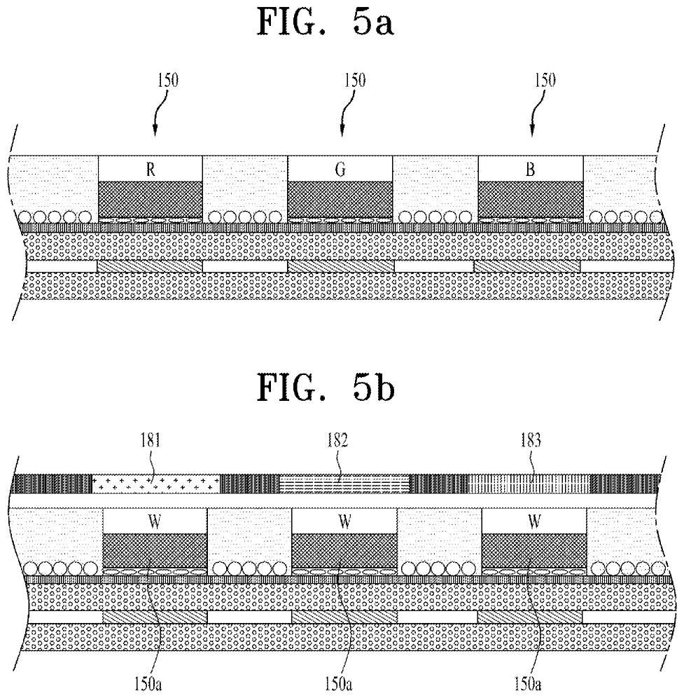

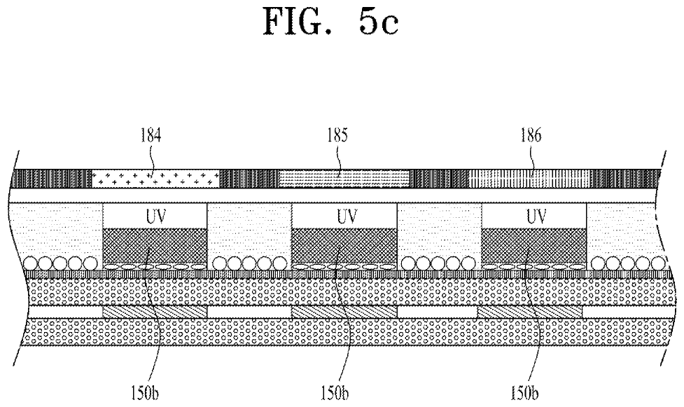

FIGS. 5A to 5C are conceptual views illustrating various examples of implementation of colors in relation to a flip-chip type semiconductor light emitting element.

As shown in FIGS. 2, 3A and 3B, the display device 100 using a passive matrix (PM) type semiconductor light emitting element is exemplified as the display device 100 using a semiconductor light emitting element. However, the examples described below are also applicable to an active matrix (AM) type semiconductor light emitting element.

The display device 100 shown in FIG. 1 may include a substrate 110, a first electrode 120, a conductive adhesive layer 130, a second electrode 140, and at least one semiconductor light emitting element 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting element 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting element 150 is connected thereto in a flip-chip form by applying heat and pressure. Thereby, the semiconductor light emitting element 150 is electrically connected to the first electrode 120 and the second electrode 140.

Referring to FIG. 4, the semiconductor light emitting element may be a flip chip-type light emitting device.

For example, the semiconductor light emitting element may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting elements 150. For example, p-type electrodes of semiconductor light emitting elements on left and right sides of an auxiliary electrode may be electrically connected to one auxiliary electrode.

More specifically, the semiconductor light emitting element 150 may be press-fitted into the conductive adhesive layer 130 by heat and pressure. Thereby, only the portions of the semiconductor light emitting element 150 between the p-type electrode 156 and the auxiliary electrode 170 and between the n-type electrode 152 and the second electrode 140 may exhibit conductivity, and the other portions of the semiconductor light emitting element 150 do not exhibit conductivity as they are not press-fitted. In this way, the conductive adhesive layer 130 interconnects and electrically connects the semiconductor light emitting element 150 and the auxiliary electrode 170 and interconnects and electrically connects the semiconductor light emitting element 150 and the second electrode 140.

The plurality of semiconductor light emitting elements 150 may constitute a light emitting device array, and a phosphor conversion layer 180 may be formed on the light emitting device array.

The light emitting device array may include a plurality of semiconductor light emitting elements having different luminance values. Each semiconductor light emitting element 150 may constitute a unit pixel and may be electrically connected to the first electrode 120. For example, a plurality of first electrodes 120 may be provided, and the semiconductor light emitting elements may be arranged in, for example, several columns. The semiconductor light emitting elements in each column may be electrically connected to any one of the plurality of first electrodes.

In addition, since the semiconductor light emitting elements are connected in a flip-chip form, semiconductor light emitting elements grown on a transparent dielectric substrate may be used. The semiconductor light emitting elements may be, for example, nitride semiconductor light emitting elements. Since the semiconductor light emitting element 150 has excellent luminance, it may constitute an individual unit pixel even when it has a small size.

As shown in FIG. 3, a partition wall 190 may be formed between the semiconductor light emitting elements 150. In this case, the partition wall 190 may serve to separate individual unit pixels from each other, and may be integrated with the conductive adhesive layer 130. For example, by inserting the semiconductor light emitting element 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting element 150. For example, the semiconductor light emitting element 150 may be a blue semiconductor light emitting element that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting element at a position of a unit pixel of red color, and the green phosphor 182 capable of converting blue light into green (G) light may be laminated on the blue semiconductor light emitting element at a position of a unit pixel of green color. Only the blue semiconductor light emitting element may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting element 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

Referring to FIG. 5A, each semiconductor light emitting element may be implemented as a high-power light emitting device emitting light of various colors including blue by using gallium nitride (GaN) as a main material and adding indium (In) and/or aluminum (Al).

In this case, each semiconductor light emitting element may be a red, green, or blue semiconductor light emitting element to form a unit pixel (sub-pixel). For example, red, green, and blue semiconductor light emitting elements R, G, and B may be alternately disposed, and unit pixels of red, green, and blue may constitute one pixel by the red, green and blue semiconductor light emitting elements. Thereby, a full-color display may be implemented.

Referring to FIG. 5B, the semiconductor light emitting element 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting element. In an embodiment, UV may be used as an excitation source of the upper phosphor in the semiconductor light emitting element.

Referring back to this example, the semiconductor light emitting element is positioned on the conductive adhesive layer to constitute a unit pixel in the display device. Since the semiconductor light emitting element has excellent luminance, individual unit pixels may be configured despite even when the semiconductor light emitting element has a small size.

Regarding the size of such an individual semiconductor light emitting element, the length of each side of the device may be, for example, 80 μm or less, and the device may have a rectangular or square shape. When the semiconductor light emitting element has a rectangular shape, the size thereof may be less than or equal to 20 μm×80 μm.

In addition, even when a square semiconductor light emitting element having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light emitting element becomes sufficiently long relatively.

Thus, in this case, it is able to implement a flexible display device having high image quality over HD image quality.

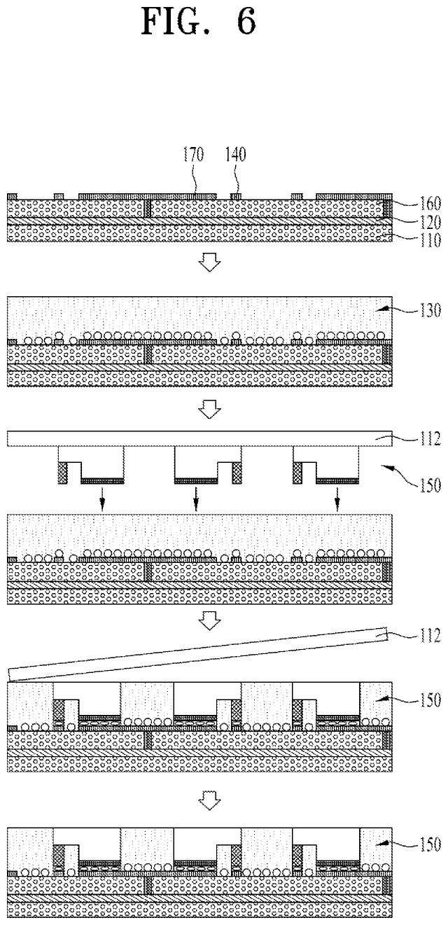

The above-described display device using the semiconductor light emitting element may be prepared by a new fabricating method. Such a fabricating method will be described with reference to FIG. 6 as follows.

FIG. 6 shows cross-sectional views of a method of fabricating a display device using a semiconductor light emitting element according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting elements 150 configuring individual pixels are located to correspond to locations of the auxiliary electrode 170 and the second electrodes 140, is disposed in a manner that the semiconductor light emitting element 150 confronts the auxiliary electrode 170 and the second electrode 140.

In this regard, the temporary 112 substrate 112 is a growing substrate for growing the semiconductor light emitting element 150 and may include a sapphire or silicon substrate.

The semiconductor light emitting element is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting element 150, the auxiliary electrode 170 and the second electrode 140 has conductivity, via which the electrodes and the semiconductor light emitting element 150 may be connected electrically. In this case, the semiconductor light emitting element 150 is inserted into the anisotropic conductive film, by which a partition may be formed between the semiconductor light emitting elements 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting elements 150 exposed externally. If necessary, the wiring substrate 110 to which the semiconductor light emitting elements 150 are coupled may be coated with silicon oxide (SiOx) or the like to form a transparent insulating layer (not shown).

In addition, a step of forming a phosphor layer on one side of the semiconductor light emitting element 150 may be further included. For example, the semiconductor light emitting element 150 may include a blue semiconductor light emitting element emitting Blue (B) light, and a red or green phosphor for converting the blue (B) light into a color of a unit pixel may form a layer on one side of the blue semiconductor light emitting element.

The above-described fabricating method or structure of the display device using the semiconductor light emitting element may be modified into various forms. For example, the above-described display device may employ a vertical semiconductor light emitting element.

Furthermore, a modification or embodiment described in the following may use the same or similar reference numbers for the same or similar configurations of the former example and the former description may apply thereto.

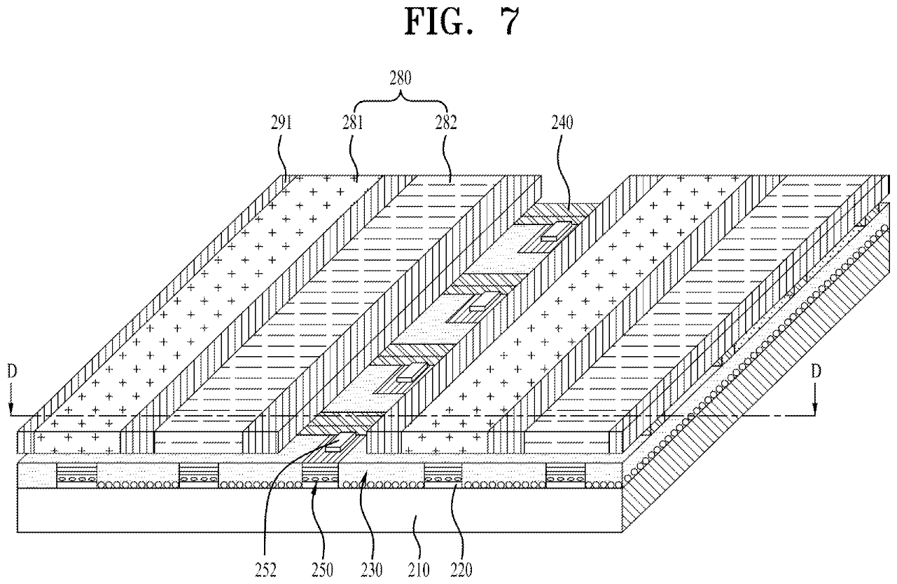

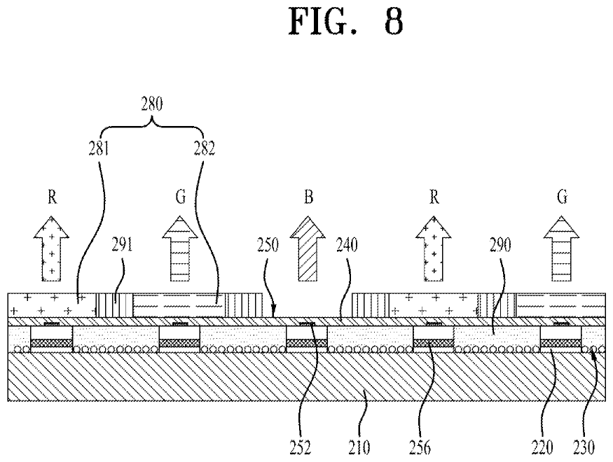

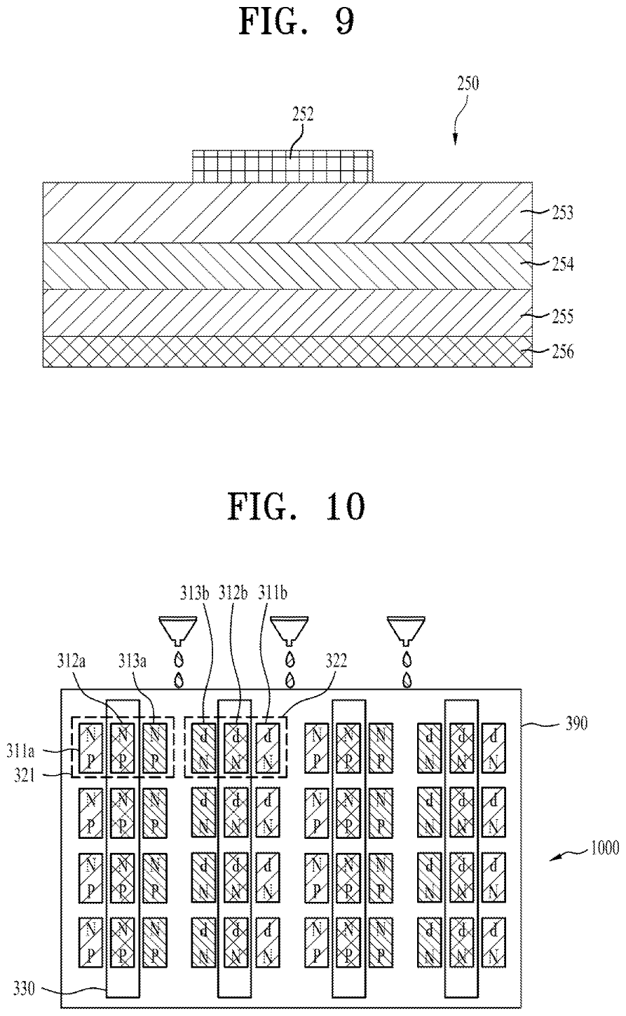

FIG. 7 is a perspective diagram of a display device using a semiconductor light emitting element according to another embodiment of the present disclosure, FIG. 8 is a cross-sectional diagram taken along a cutting line D-D shown in FIG. 8, and FIG. 9 is a conceptual diagram showing a vertical type semiconductor light emitting element shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting element 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting element 250 is connected by applying heat and pressure thereto, the semiconductor light emitting element 250 is electrically connected to the first electrode 220. In doing so, the semiconductor light emitting element 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting element 250 and the first electrode 220 as well as mechanical connection.

Thus, the semiconductor light emitting element 250 is located on the conductive adhesive layer 230, via which an individual pixel is configured in the display device. As the semiconductor light emitting element 250 has excellent luminance, an individual unit pixel may be configured in small size as well. Regarding a size of the individual semiconductor light emitting element 250, a length of one side may be equal to or smaller than 80 μm for example and the individual semiconductor light emitting element 250 may include a rectangular or square element. For example, the rectangular element may have a size equal to or smaller than 20 μm×80 μm.

The semiconductor light emitting element 250 may have a vertical structure.

Among the vertical type semiconductor light emitting elements, a plurality of second electrodes 240 respectively and electrically connected to the vertical type semiconductor light emitting elements 250 are located in a manner of being disposed in a direction crossing with a length direction of the first electrode 220.

Referring to FIG. 9, the vertical type semiconductor light emitting element 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting element 250 can dispose the electrodes at top and bottom, it is considerably advantageous in reducing a chip size.

Referring to FIG. 8 again, a phosphor layer 280 may formed on one side of the semiconductor light emitting element 250. For example, the semiconductor light emitting element 250 may include a blue semiconductor light emitting element 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting element. At a location of configuring a green unit pixel, the green phosphor 282 capable of converting blue light into green (G) light may be stacked on the blue semiconductor light emitting element. Moreover, the blue semiconductor light emitting element may be singly usable for a portion that configures a blue unit pixel. In this case, the unit pixels of red (R), green (G) and blue (B) may configure a single pixel.

Yet, the present disclosure is non-limited by the above description. In a display device to which a light emitting element of a flip chip type is applied, as described above, a different structure for implementing blue, red and green may be applicable.

Regarding the present embodiment again, the second electrode 240 is located between the semiconductor light emitting elements 250 and connected to the semiconductor light emitting elements electrically. For example, the semiconductor light emitting elements 250 are disposed in a plurality of columns, and the second electrode 240 may be located between the columns of the semiconductor light emitting elements 250.

Since a distance between the semiconductor light emitting elements 250 configuring the individual pixel is sufficiently long, the second electrode 240 may be located between the semiconductor light emitting elements 250.

The second electrode 240 may be formed as an electrode of a bar type that is long in one direction and disposed in a direction vertical to the first electrode.

In addition, the second electrode 240 and the semiconductor light emitting element 250 may be electrically connected to each other by a connecting electrode protruding from the second electrode 240. Particularly, the connecting electrode may include a n-type electrode of the semiconductor light emitting element 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting element 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light emitting element 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting element 250, there is a problem that ITO substance has poor adhesiveness to an n-type semiconductor layer. Therefore, according to the present disclosure, as the second electrode 240 is placed between the semiconductor light emitting elements 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

Referring to FIG. 8 again, a partition 290 may be located between the semiconductor light emitting elements 250. Namely, in order to isolate the semiconductor light emitting element 250 configuring the individual pixel, the partition 290 may be disposed between the vertical type semiconductor light emitting elements 250. In this case, the partition 290 may play a role in separating the individual unit pixels from each other and be formed with the conductive adhesive layer 230 as an integral part. For example, by inserting the semiconductor light emitting element 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light emitting elements 250, the partition 290 may be located between the vertical type semiconductor light emitting element 250 and the second electrode 240 each. Therefore, an individual unit pixel may be configured using the semiconductor light emitting element 250. Since a distance between the semiconductor light emitting elements 250 is sufficiently long, the second electrode 240 can be placed between the semiconductor light emitting elements 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

As described above, the semiconductor light emitting element may constitute a unit pixel in the display device. The semiconductor light emitting element may have excellent luminance, and may constitute individual pixels even in a small size. Accordingly, a full-color display in which red (R), green (G), and blue (B) unit pixels constitute one pixel can be implemented by the semiconductor light emitting elements.

In order to implement a display device emitting red, green, and blue light as described above, a process of transferring semiconductor light emitting elements onto a wiring substrate is required to connect the semiconductor light emitting elements to electrodes. A method for efficiently performing the transfer operation by reducing the number of transfer actions will hereinafter be described in detail.

FIG. 10 is a top view schematically illustrating a first arrangement of pixels in a transfer substrate according to an embodiment of the present disclosure.

Referring to FIG. 10, the transfer substrate 1000 may include a first pixel 321 and a second pixel 322. The first pixel 321 and the second pixel 322 may be located adjacent to each other. Each of the first pixel 321 and the second pixel 322 may include a plurality of unit pixels 310. FIG. 10 illustrates an example in which each of the first pixel 321 and the second pixel 322 includes three unit pixels. For example, the first pixel 321 may include three unit pixels (311a, 312a, 313a) respectively representing a red pixel (R), a green pixel (G), and a blue pixel (B), and the second pixel 322 may include three unit pixels 311a, 312a, and 313a respectively representing a red pixel (R), a green pixel (G), and a blue pixel (B).

Some of the plurality of unit pixels may include a semiconductor light emitting element of a first color, and each of the remaining unit pixels may include a semiconductor light emitting element of a first color and a light conversion layer configured to convert the first color into a second or third color. The first color may be blue.

For example, each of the unit pixels (311a, 312a, 313a) of the first pixel 321 may include a blue light emitting element, and each of some unit pixels (311a, 313a) of the unit pixels (311a, 312a, 313a) of the first pixel 321 may include a light conversion layer that converts a blue color to a red or green color. The unit pixels 310 of the second pixel 322 may also be configured to have the same configuration.

In the transfer substrate 1000 according to embodiments of the present disclosure, the unit pixel 313a located adjacent to the second pixel 322 from among the plurality of unit pixels (311a, 312a, 313a) included in the first pixel 321 may include a light conversion layer of the same color as the unit pixel 311b located adjacent to the first pixel 321 from among the plurality of unit pixels (311b, 312b, 313b) included in the second pixel 322. FIG. 10 illustrates an example in which colors represented by the unit pixel 313a of the first pixel 321 and the unit pixel 311b of the second pixel 322 adjacent to the first pixel 321 are equally changed from a blue color to a green color.

The transfer substrate may include a temporary substrate 390, a plurality of semiconductor light emitting elements of a first color disposed on the temporary substrate 390, and a light conversion layer formed on at least a portion of the semiconductor light emitting elements to convert the first color into a second color or a third color.

Unit pixels 310, each of which includes one semiconductor light emitting element, from among a plurality of semiconductor light emitting elements having a first color, and a pixel 320 including the plurality of unit pixels 310 may be disposed on the temporary substrate 390.

Specifically, the transfer substrate may include a plurality of pixels 320 each including a plurality of unit pixels 310, resulting in formation of the transfer substrate. In addition, each pixel 320 may include unit a unit pixel 310 of a first color, a unit pixel 310 of a second color, and a unit pixel 310 of a third color, for example, RGB unit pixels 310. That is, according to embodiments of the present disclosure, all of red, blue, and green light emitting elements may be included in one transfer substrate, so that all of the red, green, and blue light emitting elements can be transferred through one laser scanning process in a lift-off process. Accordingly, as the number of transfer actions decreases, transfer efficiency can be improved.

The pixel 320 may include a first pixel 321 and a second pixel 322 adjacent to each other. The pixel 320 may include, for example, three unit pixels 310, and the three unit pixels 310 may be arranged in a line when viewed from above. When viewed from above the first pixel 321, the first pixel 321 may include a unit pixel 311a having a second color, a unit pixel 312a having a first color, and a unit pixel 313a having a third color. In the first pixel 321, the unit pixel 311a, the unit pixel 312a, and the unit pixel 313a may be sequentially arranged in a clockwise direction. When viewed from above the second pixel 322, the second pixel may include a unit pixel 313b having a third color, a unit pixel 312b having a second color, and a unit pixel 311b having a first color. In the second pixel 322, the unit pixel 313b, the unit pixel 312b, and the unit pixel 311b may be sequentially arranged in a clockwise direction.

That is, the unit pixel 310 disposed adjacent to each of the first pixel 321 and the second pixel 322 may be converted into a unit pixel 313 of the same color (i.e., the third color).

In order for the unit pixels included in adjacent unit pixels 320 to emit the same color of light, pixel electrodes of the plurality of unit pixels 310 included in the adjacent first pixel 321 may be formed to be point-symmetrical to pixel electrodes of the plurality of unit pixels included in the second pixel 322.

Specifically, the first pixel 321 and the second pixel 322, which are two adjacent unit pixels, may be configured such that a first conductive electrode (el-1) and a second conductive electrode (el-2) have different arrangements. For example, as shown in FIG. 10, the first pixel 321 and the second pixel 322 adjacent to each other may be arranged to have an angle of 180 degrees (i.e., 180°) therebetween. In this case, when the second pixel 322 is rotated by 180 degrees (i.e., 180°), the first pixel 321 and the second pixel 322 may serve as one kind of pixels 320 having the same arrangement.

That is, the unit pixels 320 disposed on the temporary substrate 390 according to the embodiments of the present disclosure may be disposed to rotate 180 degrees (i.e., 180°) from each other, but may have a substantially single arrangement. In this case, the first pixel and the second pixel need not be managed separately from each other, resulting in higher efficiency in system operation.

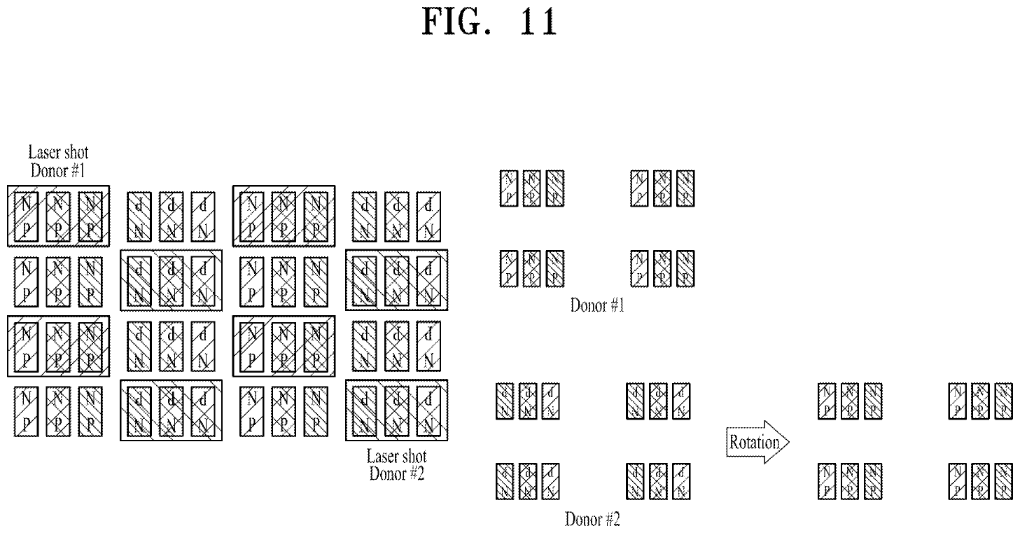

FIG. 11 is a schematic diagram illustrating a structure for transferring the transfer substrate to which a first arrangement of pixels is applied onto a wiring substrate.

Donor #1 including the first pixel and Donor #2 including the second pixel can be obtained from the transfer substrate according to the embodiments of the present disclosure. At this time, since Donor #1 formed with the first pixel and Donor #2 formed with the second pixel need not be managed separately from each other because Donor #1 having been rotated can operate as the same donor as Donor #1, resulting in higher efficiency in system operation.

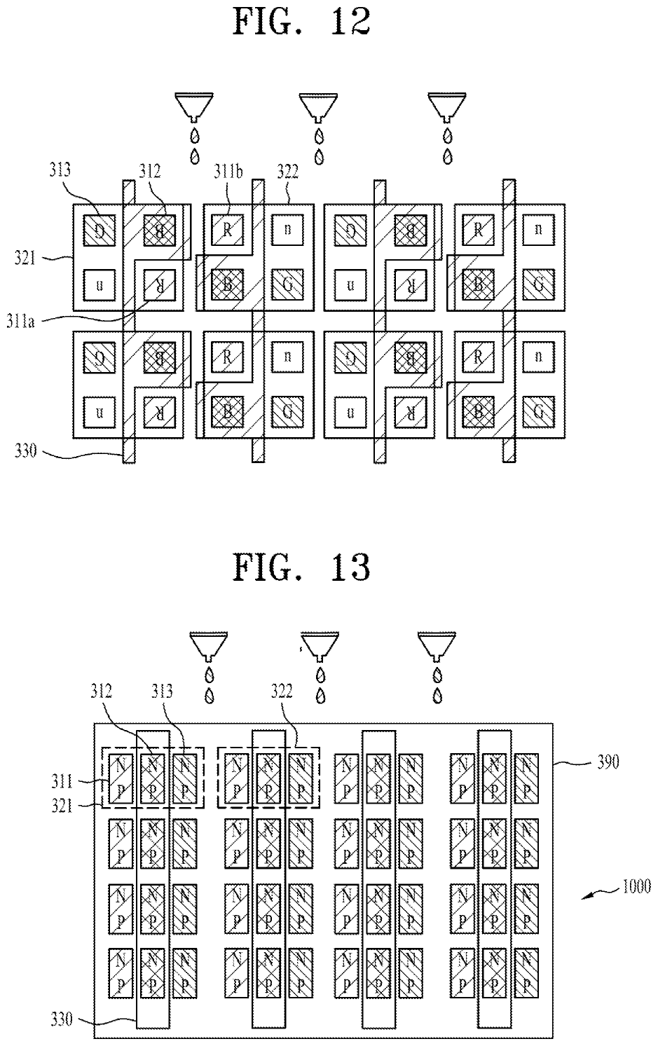

FIG. 12 is a top view illustrating an example case in which unit pixels are applied to a single chip in a transfer substrate according to an embodiment of the present disclosure.

A single chip including at least one semiconductor light emitting element may be formed according to the embodiments of the present disclosure. In order to form a single chip indicating the first color, the second color, and the third color, a barrier 330 may be disposed on the semiconductor light emitting element 312 of the first color. In this case, in the first pixel 321 and the second pixel 322 adjacent to each other, the light conversion layer 330 for converting the first color into the same color within the first pixel 321 may be disposed adjacent to the light conversion layer 330 for converting the first color into the same color within the second pixel 322. That is, a single chip may be disposed such that the unit pixel 311a indicating the second color in the first pixel 321 and the unit pixel 311b indicating the second color in the second pixel 322 are disposed adjacent to each other.

Unlike FIG. 12, the barrier 330 may be disposed to correspond to the first color semiconductor light emitting element 312, as well as to cover a common electrode (n) connected to the chip. However, this is merely an example, and the barrier 330 may not be disposed on the common electrode (n).

A single chip may be formed to emit red light, blue light, and green light, and may correspond to one pixel 320 described above. That is, one pixel 320 may be a single chip that emits RGB light. Although FIG. 12 shows a single chip that includes one semiconductor light emitting device displaying the first color, one semiconductor light emitting element displaying the second color, and one semiconductor light emitting element displaying the third color, the scope or spirit of the embodiments of the present disclosure is not limited thereto. For example, the embodiments of the present disclosure may also be applied to a single chip that includes a unit pixel displaying the first color and the second color. For example, the embodiments of the present disclosure may also be applied to a single chip that includes two unit pixels 312 of the first color and only one of the unit pixel 311 of the second color and the unit pixel 313 of the third color.

When the second pixel is rotated in the same direction as the first pixel, the electrode between semiconductor light emitting devices may be problematic. However, according to the embodiments of the present disclosure, the electrode for the semiconductor light emitting device displaying the second color and the electrode for the semiconductor light emitting device displaying the third color may be used regardless of rotation by 180 degrees (180°). That is, even if the connection to the electrode is changed by 180° rotation, the red and green signals are changed and driven, thereby solving the problem caused by the 180° rotation of the chip during the self-assembly process.

FIG. 13 is a top view illustrating a second arrangement of pixels in a transfer substrate according to an embodiment of the present disclosure. Redundant configurations will be described with reference to FIG. 10.

The transfer substrate 1000 may include a first pixel 321 and a second pixel 322. The first pixel 321 and the second pixel 322 may be disposed adjacent to each other. Each of the first pixel 321 and the second pixel 322 may include a plurality of unit pixels 310. FIG. 10 illustrates an example in which each of the first pixel 321 and the second pixel 322 includes three unit pixels. For example, the first pixel 321 may include three unit pixels 311a, 312a, and 313a representing red light (R), green light (G), and blue light (B), respectively, and the second pixel 322 may include three unit pixels 311a, 312a, and 313a representing R, G, and B, respectively.

The transfer substrate may include a temporary substrate 390, a plurality of first color semiconductor light emitting elements disposed on the temporary substrate 390, and a light conversion layer formed on at least a portion of the semiconductor light emitting elements to convert a first color into a second or third color.

A unit pixel 310 including any one of the plurality of semiconductor light emitting elements of the first color, and a pixel 320 including a plurality of unit pixels 310 are disposed on the temporary substrate 390.

The transfer substrate may include a plurality of pixels 320, each of which includes a plurality of unit pixels 310, resulting in formation of the transfer substrate. In addition, each pixel 320 may include R, G, and B unit pixels. That is, according to the embodiments of the present disclosure, all red, blue, and green light emitting elements may be included in one transfer substrate, so that the R, G, and B light emitting elements can be transferred through only one laser scan in a lift-off process. Accordingly, as the number of transfer actions is reduced, transfer efficiency can increase.

In this case, in order to emit the same color between the unit pixels included in adjacent unit pixels, the transfer substrate 1000 may be configured such that pixel electrodes of the plurality of unit pixels 310 included in the first pixel 321 are formed to be line-symmetrical to pixel electrodes of the unit pixels included in the second pixel 322.

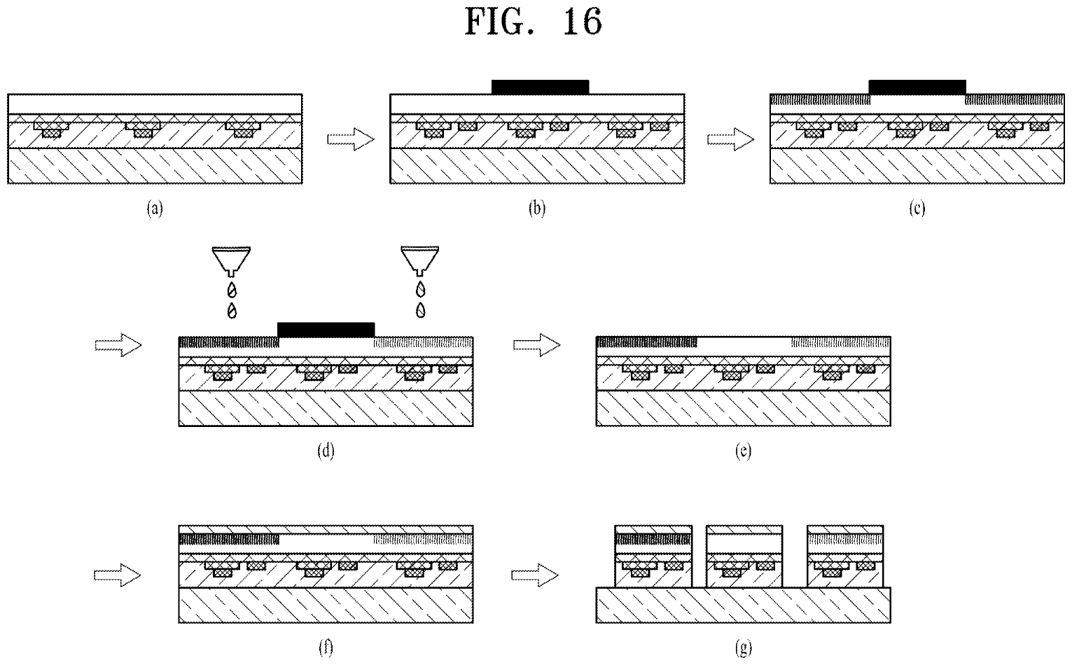

Specifically, the first pixel 321 and the second pixel 322 may be configured such that the first conductive electrode and the second conductive electrode have the same arrangement but the order of the unit pixels 310 of the first conductive electrode is different from the order of the unit pixels 310 of the second conductive electrode. For example, as shown in FIG. 16, the first pixel 321 and the second pixel 322 adjacent to each other may be arranged to have the same direction. In this case, the first pixel 321 and the second pixel 322 may be heterogeneous pixels 320 having different color arrangements.

That is, the unit pixels disposed on the transfer substrate according to the embodiments of the present disclosure may have the same structure but substantially have at least two or more arrangements. In this case, there is no need to rotate the unit pixels in order to use the second pixel, resulting in increased transfer efficiency. The above-described structure can be applied to any structure of the vertical light emitting elements and the horizontal light emitting elements, so that the application range of the present disclosure is large.

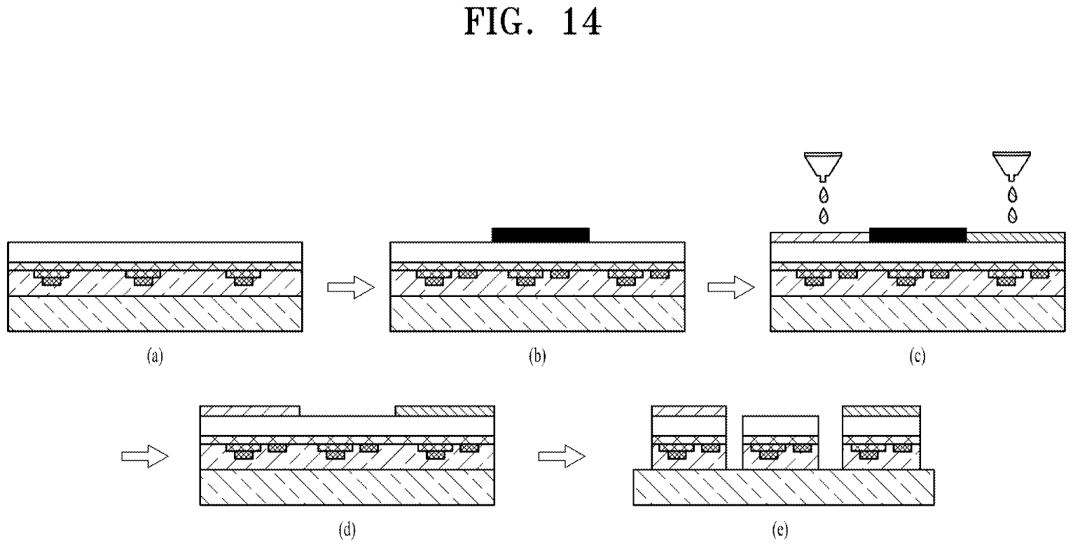

FIGS. 14(a) to 14(e) are cross-sectional views illustrating examples of a method for manufacturing the display device using semiconductor light emitting elements according to embodiments of the present disclosure.

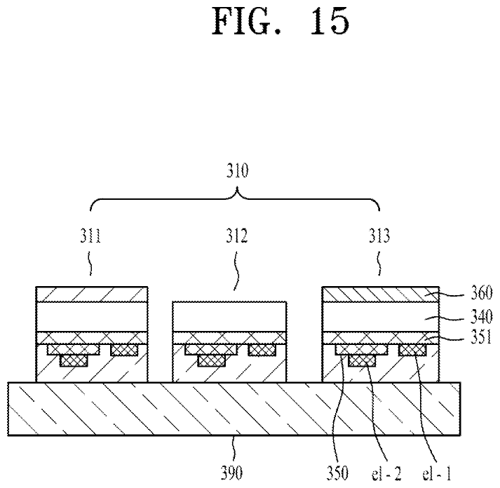

FIG. 15 is a schematic cross-sectional view illustrating the semiconductor light emitting elements according to an embodiment of the present disclosure. Hereinafter, FIG. 14 will be described with reference to reference numerals shown in FIG. 15.

FIG. 14(a) is a cross-sectional view illustrating a method for manufacturing the semiconductor light emitting devices.

A method for manufacturing the display device may include forming a plurality of semiconductor light emitting elements including first-color semiconductor light emitting elements.

Specifically, a first conductive semiconductor layer 340, an active layer 351, a second conductive semiconductor layer 350, a first conductive electrode (el-1), and a second conductive electrode (el-2) may be sequentially stacked on a base substrate (not shown), resulting in formation of the semiconductor light emitting element. For example, a Metal-Organic Chemical Vapor Deposition (MOCVD) method may be used for the growth of the semiconductor layer, but the scope or spirit of the present disclosure is not limited thereto.

The base substrate may be formed of a material having light transmission properties, for example, a material such as sapphire, GaN, or ZnO, but is not limited thereto. In addition, a material having excellent thermal conductivity can be formed, and a conductive substrate or an insulating substrate may be used as the base substrate. For example, a SiC substrate having greater thermal conductivity than a sapphire substrate may be used as the base substrate.

The first conductive semiconductor layer 340 may be an N-type semiconductor layer, and may be a nitride semiconductor layer such as an n-GaN layer. The second conductive semiconductor layer 350 is a P-type semiconductor layer, and may be a nitride semiconductor layer such as a p-GaN layer. However, the scope or spirit of the present disclosure is not limited thereto, and vice versa.

The first conductive electrode (el-1) and the second conductive electrode (el-2) may be formed on the first conductive semiconductor layer 340 and the second conductive semiconductor layer 350 such that the first conductive electrode (el-1) can be connected to the first conductive semiconductor layer 340 and the second conductive electrode (el-2) can be connected to the second conductive semiconductor layer 350. The first conductive electrode (el-1) may be an N-type conductive electrode, and the second conductive electrode (el-2) may be a P-type conductive electrode, but the scope or spirit of the present disclosure is not limited thereto, and vice versa.

The semiconductor light emitting element may be a blue semiconductor light emitting element, but is not limited thereto. However, the semiconductor light emitting element may also be a light emitting element of another color, such as red or green, as needed.

An insulating layer (not shown) may be disposed on the semiconductor light emitting element. Specifically, the insulating layer may be disposed on the semiconductor light emitting element to surround the first conductive semiconductor layer 340 and the second conductive semiconductor layer 350. The insulating layer may be, for example, a nitride-based insulating layer (SiNx) or a silicon (SiO₂)-based material. Since the insulating layer is disposed as described above, the first conductive semiconductor layer 340 and the second conductive semiconductor layer 350 can be electrically disconnected from each other. That is, the semiconductor light emitting element can be stabilized.

The temporary substrate 390 may be attached to the insulating layer through bonding thereof to the insulating layer. The temporary substrate may be disposed on the opposite side of the semiconductor light emitting element and adhered to the insulating layer. After the plurality of semiconductor light emitting elements each including the insulating layer is fixed by the temporary substrate 390, the base substrate may be removed.

FIG. 14(b) is a cross-sectional view illustrating a barrier disposed on the first conductive semiconductor layer.

A barrier 330 may be disposed on one side of some of the semiconductor light emitting elements.

The barrier 330 may be disposed on one surface of the plurality of semiconductor light emitting elements facing the temporary substrate 390 to include some of the plurality of semiconductor light emitting elements. Specifically, the barrier 330 may be disposed on the first conductive semiconductor layer 340 in a direction opposite to the first and second conductive electrodes (el-1, el-2) so as to correspond to some of the plurality of semiconductor light emitting elements. In this case, the semiconductor light emitting element corresponding to the barrier 330 may be a sub-pixel (i.e., a unit pixel) 310 of the first color, and may emit, for example, blue light.

The barrier 330 may use a hydrophobic material having low wetting properties. Specifically, a solvent that is incompatible with a fluorescent material to be described later can be used. As a result, color mixing between solvents separated by the barrier can be prevented.

The barrier 330 may be disposed at the center of the plurality of semiconductor light emitting elements so that the blue semiconductor light emitting element can be disposed at the center of the semiconductor light emitting elements.

FIG. 14(c) is a cross-sectional view illustrating a light conversion layer printed on the semiconductor light emitting elements.

A method for forming the display device may include forming a light conversion layer that converts the first color into the second or third color in the semiconductor light emitting element including no barrier.

The light conversion layer may display a color different from the color emitted by the semiconductor light emitting element. For example, when the semiconductor light emitting element is a blue semiconductor light emitting element, the light conversion layer may include red or blue color.

The light conversion layer may be formed by an inkjet method. When inkjet printing is used, a material sprayed by a nozzle may be used by mixing a fluorescent material such as a phosphor with a material such as silicon. Since the light conversion layer is not printed on a portion corresponding to the blue unit pixel by the barrier, the light conversion layer corresponding to the red and green unit pixels may be printed.

In order to easily print the light conversion layer, the arrangement of unit pixels may be adjusted. Specifically, the method may further include converting a color of at least one semiconductor light emitting element, which is located adjacent to the semiconductor light emitting element to be converted into the second color, into the second color. In addition, the method may further include converting a color of at least one semiconductor light emitting element, which is located adjacent to the semiconductor light emitting element to be converted into the third color, into the third color.

For example, three unit pixels may be arranged to form one unit pixel. In this case, the three unit pixels may be arranged to be unit pixels respectively emitting red, blue, and green light, or may be arranged to be unit pixels respectively emitting green, blue, and red light.

In this case, each unit pixel may be arranged to emit the same color as a unit pixel of a neighboring unit pixel. For example, the first pixel 321 may be arranged in order of red, blue, and green unit pixels. In this case, the second pixel 322 disposed adjacent to the first pixel 321 may be disposed in the order of green, blue, and red unit pixels. That is, each green unit pixel included in each of the first pixel 321 and the second pixel 322 may be disposed adjacent to each other.

Since the light emitting elements emitting the same color of light are disposed between adjacent unit pixels, the light conversion layer corresponding to the plurality of unit pixels may be printed through a single printing process.

Through the above process, for example, a semiconductor light emitting element emitting blue light may be converted into a semiconductor light emitting element emitting blue, red, or green light. Accordingly, a display device emitting blue, red, or green light can be obtained by transferring the temporary substrate on which light conversion is performed onto the wiring substrate.

FIG. 14(d) is a cross-sectional view illustrating a method for printing the light conversion layer and removing the barrier. FIG. 14(e) is a cross-sectional view illustrating a structure in which singulation of LEDs is performed to correspond to each unit pixel.

The singulation may be performed by forming the plurality of light emitting elements as one group. Specifically, the singulation may be performed on the basis of a unit pixel including a plurality of sub-pixels. For example, when the RGB-type light emitting elements are required, singulation may be performed to form only one unit pixel including red, blue, and green sub-pixels.

FIG. 15 is a schematic cross-sectional view of a semiconductor light emitting element manufactured according to the manufacturing method of FIG. 14.

Referring to FIG. 15, a transfer substrate manufactured according to the embodiments of the present disclosure may include a temporary substrate 390, a first conductive electrode (el-1), a second conductive electrode (el-2), a first conductive semiconductor layer 340 in which the first conductive electrode (el-1) is disposed, a second conductive semiconductor layer 350 disposed on the first conductive semiconductor layer 340, an active layer 351 disposed between the first conductive semiconductor layer 340 and the second conductive semiconductor layer 350, an insulating layer 380 formed to surround the semiconductor light emitting element, and a light conversion layer 360 disposed on the first conductive semiconductor layer 340.

The temporary substrate 390 may be a flat substrate, and may use a material through which laser or ultraviolet (UV) light can be transmitted. In the process of transferring the base substrate including the semiconductor light emitting element 150 onto the temporary substrate 390, an adhesive layer (not shown) may be further included to improve adhesive force with the temporary substrate 390. The adhesive layer may include, for example, a thermosetting adhesive such as epoxy, acrylate, silicone, or the like.

In addition, an isolation layer (not shown) may be further disposed between the temporary substrate and the adhesive layer in order to be easily transferred onto the wiring substrate acting as a final substrate. At this time, the isolation layer may be a layer in which deformation occurs by heat caused by laser or ultraviolet (UV) light. For example, an organic or inorganic layer may be used as the isolation layer.

The first conductive semiconductor layer 340 may be an N-type semiconductor layer, and may be a nitride semiconductor layer such as an n-GaN layer. The second conductive semiconductor layer 350 may be a P-type semiconductor layer, and may be a nitride semiconductor layer such as a p-GaN layer. However, the scope or spirit of the present disclosure is not limited thereto, and vice versa.

The first conductive electrode (el-1) and the second conductive electrode (el-2) may be formed on the first conductive semiconductor layer 340 and the second conductive semiconductor layer 350, such that the first conductive electrode (el-1) and the second conductive electrode (el-2) are respectively connected to the first conductive semiconductor layer 340 and the second conductive semiconductor layer 350. The first conductive electrode (el-1) may be an N-type conductive electrode, and the second conductive electrode (el-2) may be a P-type conductive electrode, but the scope or spirit of the present disclosure is not limited thereto, and vice versa.

A structure in which the first conductive semiconductor layer 340, the second conductive semiconductor layer 350, the active layer 351, the first conductive electrode (el-1), and the second conductive electrode (el-2) are stacked and connected to each other will hereinafter be referred to as a semiconductor light emitting element 150. The semiconductor light emitting element 150 may be a blue LED. However, LEDs of other colors such as red and blue colors may also be used as needed.

The insulating layer 380 may be formed on the semiconductor light emitting element 150, and may be disposed between the temporary substrate 390 and the semiconductor light emitting element 150. Specifically, the insulating layer 380 may be disposed on the semiconductor light emitting element 150 to surround the first conductive semiconductor layer 340 and the second conductive semiconductor layer 350. The insulating layer 380 may be, for example, a nitride-based insulating layer (SiNx) or a silicon (SiO₂)-based material. Since the insulating layer 380 is disposed as described above, the first conductive semiconductor layer 340 and the second conductive semiconductor layer 350 may be electrically disconnected from each other. That is, the semiconductor light emitting element 150 can be stabilized.

The transfer substrate including the semiconductor light emitting element 150 may display a first color, a second color, and a third color. In this case, each of the pixel 312 emitting light of the first color, the pixel 311 emitting light of the second color, and the pixel 313 emitting light of the third color may be referred to as a unit pixel 310.

The light conversion layer 360 may be formed on the first conductive semiconductor layer 340 to correspond to each unit pixel 310. When the semiconductor light emitting element 150 displays the first color, the light conversion layer 360 may display the second color and the third color. For example, when the semiconductor light emitting element 150 emits blue (first color) light, the blue color is converted into the red (second color) or green (third color) color while passing through the light conversion layer 360 to emit light. Hereinafter, for better understanding of the present disclosure, a semiconductor light emitting element displaying the second color and a semiconductor light emitting element corresponding to a light conversion layer displaying the second color may be used together.

Specifically, the plurality of semiconductor light emitting elements 150, that includes the first color emitted by the semiconductor light emitting element 150 and the second and third colors converted by the light conversion layer 360, may be used as one pixel 320. One pixel 320 may include, for example, three unit pixels 310. However, this is only an example, and the type or number of unit pixels included in one pixel 320 is not limited thereto. For example, a unit pixel that includes two sub-pixels emitting light of the first color, one sub-pixel emitting light of the second color, and one sub-pixel emitting light of the third color may also be used.

To this end, the light conversion layer 360 may be formed by an inkjet method. When inkjet printing is used, a material sprayed by a nozzle may be used by mixing a fluorescent material such as a phosphor with a material such as silicone. Since the light conversion layer is not printed on a portion corresponding to the blue unit pixel by the barrier, the light conversion layer corresponding to the red and green unit pixels may be printed.

At this time, as shown in FIG. 10 described above, in the first pixel 321 and the second pixel 322 disposed adjacent to each other, unit pixels 313 displaying the same color are disposed adjacent to each other. That is, in the first pixel 321 and the second pixel 322, unit pixels may be arranged so that light emitting elements emitting the same wavelength may be adjacent to each other.

Since the unit pixels of the same color are disposed adjacent to each other, the light conversion layer can be simultaneously formed on two unit pixels while the nozzle is moved once during the inkjet process. Accordingly, a fabrication margin can be improved during formation of the light conversion layer.

For example, when viewed from the top, in order to form unit pixels emitting RGB light, the unit pixels 310a included in the first pixel 321 may be arranged in the order of a red pixel 311a, a blue pixel 312a, and a green pixel 313a. The unit pixels 310b included in the second pixel 322 adjacent to the first pixel 321 may be arranged in the order of a green pixel 313b, a blue pixel 312b, and a red pixel 311b. That is, the green unit pixel 313a of the first pixel 321 and the green unit pixel 313b of the second pixel 322 may be arranged adjacent to each other, so that the light conversion layer can be simultaneously formed on the two unit pixels.

FIGS. 16(a) to 16(g) are cross-sectional views illustrating examples of a method for manufacturing the display device using semiconductor light emitting elements according to embodiments of the present disclosure. Redundant configurations will be described with reference to the technology of FIG. 14.

FIG. 16(a) shows a method of manufacturing a horizontal light emitting element.

Specifically, a first conductive semiconductor layer 340, an active layer 351, a second conductive semiconductor layer 350, a first conductive electrode (el-1), and a second conductive electrode (el-2) are sequentially stacked on the base substrate, resulting in formation of the semiconductor light emitting element.

An insulating layer (not shown) may be disposed on the manufactured semiconductor light emitting element. Specifically, the insulating layer may be disposed on the semiconductor light emitting element in a format surrounding the first conductive semiconductor layer 340 and the second conductive semiconductor layer 350.

FIG. 16(b) is a cross-sectional view illustrating a structure in which a barrier 330 is disposed on the first conductive semiconductor layer.

The barrier 330 may be disposed on the temporary substrate 390 including the plurality of semiconductor light emitting elements. Specifically, the barrier 330 may be disposed on the first conductive semiconductor layer 340 in a direction opposite to the first and second conductive electrodes so as to correspond to some of the plurality of semiconductor light emitting elements. In this case, the semiconductor light emitting element corresponding to the barrier 330 may be a sub-pixel (i.e., a unit pixel), and may emit, for example, blue light.

As shown in FIG. 10 described above, the barrier may be located at the center of the plurality of semiconductor light emitting elements so that the blue semiconductor light emitting element is located at the center of the semiconductor light emitting elements.

FIG. 16(c) is a cross-sectional view illustrating a structure in which a nanopore structure is formed in the first semiconductor layer.

The forming the light conversion layer of FIG. 14 may further include forming the nanopore structure in the first conductive semiconductor layer 340.

In order to form the nanopore structure in the first conductive semiconductor layer 340, an electrochemical etching process may be performed on the surface of the first conductive semiconductor layer 340. For example, the doping concentration and the etching voltage of the first conductive semiconductor layer 340 can be adjusted. When the etching process is performed, by the barrier 330 disposed on the first conductive semiconductor layer 340, the nanopore structure may not be formed on the first conductive semiconductor layer 340 in which the barrier 330 is disposed, and the nanopore structure may be formed on the first conductive semiconductor layer 340 in which the barrier 330 is not disposed.

FIGS. 16(d) and 16(e) are cross-sectional views illustrating a structure in which the light conversion layer is printed on the nanopore structure and a structure from which the barrier is removed after completion of such printing.

The method for manufacturing the display device may further include injecting a wavelength conversion material into the nanopore structure.

The light conversion layer 360 may be formed by an inkjet method. When inkjet printing is used, a wavelength conversion material may be sprayed by a nozzle. For example, a wavelength conversion material such as a quantum dot (QD) may be mixed with a material such as silicone. That is, quantum dots may be impregnated into the nanopore structure using the inkjet method.

Since quantum dots are printed in the nanopore structure, blue light emitted from the semiconductor light emitting element can be converted into another color of light. For example, a red quantum dot emitting light having a wavelength of about 620 nm to about 750 nm and a green quantum dot emitting light having a wavelength of about 495 nm to about 570 nm may be printed, so that a display device capable of emitting RGB light can be obtained. That is, a portion corresponding to the barrier may be a blue unit pixel, a portion corresponding to the red quantum dot may be a red unit pixel, and a portion corresponding to the green quantum dot may be a green unit pixel.

As shown in FIG. 10, arrangement of unit pixels may be adjusted to easily print the light conversion layer. For example, three unit pixels may be arranged to form one unit pixel. In this case, the three unit pixels may be arranged to be unit pixels emitting red, blue, and green light, or may be arranged to be unit pixels emitting green, blue, and red light.

At this time, each unit pixel may emit the same color as the unit pixel of the adjacent unit pixel. For example, as shown in FIG. 10, the first pixel 321 may be arranged in order of a red unit pixel, a blue unit pixel, and a green unit pixel. In this case, the second pixel 322 disposed adjacent to the first pixel 321 may be arranged in the order of the green unit pixel, the blue unit pixel, and the red unit pixel. That is, each green unit pixel included in the first pixel 321 may be disposed adjacent to each green unit pixel included in the second pixel 322.

Since the light emitting elements emitting the same color are disposed between adjacent unit pixels, the light conversion layer 360 corresponding to a plurality of unit pixels may be printed through a single printing process.

Through the above process, a semiconductor light emitting device emitting, for example, blue light may be converted into a semiconductor light emitting device emitting blue, red, and green light. Accordingly, a display device emitting blue light, red light, and green light can be obtained by transferring the temporary substrate on which light conversion is performed onto the wiring substrate.

A structure in which a wavelength conversion material is printed or a structure in which a wavelength conversion material is included in the nanopore structure will hereinafter be referred to as a light conversion layer 360.

FIG. 16(f) is a cross-sectional view illustrating a structure in which a protective layer 370 is formed on the first conductive semiconductor layer 340 to cover the light conversion layer.

In order to protect the nanopore structure including quantum dots, the method for forming the display device may further include forming a protective layer 370 on the first conductive semiconductor layer 340 to cover the light conversion layer 360. The protective layer 370 may be formed using, for example, a deposition process such as a chemical vapor deposition (CVD) process.

In FIGS. 16(e) and 16(f), the barrier 330 on the first conductive semiconductor layer 340 is first removed and the protective layer 370 is then formed. On the contrary, after the protective layer 370 is formed, the barrier 330 may also be removed from the first conductive semiconductor layer 340. In this case, although the protective layer 370 is formed only on the first conductive semiconductor layer 340 where the barrier 330 is not located, the scope or spirit of the protective layer 370 is not limited thereto, and the purpose of the protective layer 370 configured to protect the nanopore structure can also be easily achieved.

FIG. 16(g) is a cross-sectional view illustrating that singulation of a semiconductor wafer is performed to correspond to each unit pixel.

Singulation may be performed by forming the plurality of light emitting elements as one group. Specifically, the singulation may be performed on the basis of a unit pixel including a plurality of sub-pixels. For example, when the RGB -type light emitting elements are required, singulation may be performed to form only one unit pixel including red, blue, and green sub-pixels.

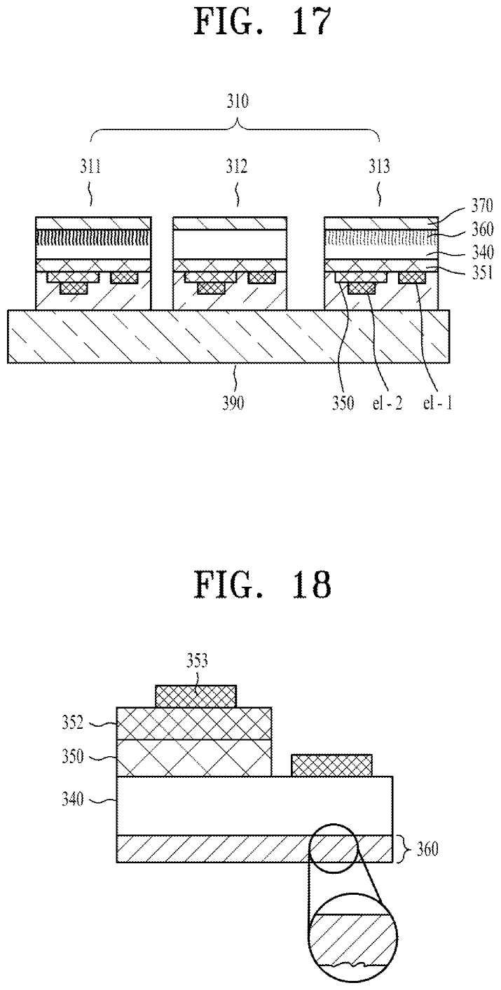

FIG. 17 is a schematic cross-sectional view illustrating a semiconductor light emitting element manufactured according to the manufacturing method of FIG. 16. For a detailed description of the overlapping structure, refer to technology of the above embodiment.

The transfer substrate manufactured according to the embodiments of the present disclosure may include a temporary substrate 390, a first conductive electrode (el-1), a second conductive electrode (el-2), a first conductive semiconductor layer 340 in which the first conductive electrode (el-1) is disposed, a second conductive semiconductor layer 350 in which the second conductive electrode (el-2) is disposed while being disposed on the first conductive semiconductor layer 340, an active layer 351 disposed between the first conductive semiconductor layer 340 and the second conductive semiconductor layer 350, an insulating layer 380 formed to surround the semiconductor light emitting elements, and a light conversion layer 360 formed on the first conductive semiconductor layer 340.

A detailed description of the temporary substrate 390, the first conductive electrode (el-1), the second conductive electrode (el-2), the first and second conductive semiconductor layers 340 and 352, the active layer 351, and the insulating layer 380 will be given in detail with reference to FIG. 15.

The light conversion layer 360 may be formed on the first conductive semiconductor layer 340 to correspond to each unit pixel 310, and may be formed in the first conductive semiconductor layer 340. When the semiconductor light emitting element 150 displays the first color, the light conversion layer 360 may display the second color and the third color. For example, when the semiconductor light emitting element 150 emits blue light, the blue light may be converted into red or green light while passing through the light conversion layer 360 to emit light.

The light conversion layer 360 may be formed in the first conductive semiconductor layer 340 in a height direction from the surface of the first conductive semiconductor layer 340, and may be formed in a shape of the nanopore structure.

The nanopore structure may be formed by performing an electrochemical etching process on the first conductive semiconductor layer. The shape of the nanopore structure may be any structure having a nanoscale. For example, the shape of the nanopore structure may have various cross sections, such as a circular shape or a polygonal shape such as a square.

A wavelength conversion material such as a quantum dot may be included in the nanopore structure. Since the quantum dots are printed in the nanopore structure, blue light emitted from the semiconductor light emitting element may be converted into another color of light. For example, red quantum dots emitting light having a wavelength of about 620 nm to about 750 nm and green quantum dots emitting light having a wavelength of about 495 nm to about 570 nm may be printed to implement a display device capable of emitting RGB light. That is, a portion corresponding to the barrier may be a blue unit pixel, a portion corresponding to the red quantum dot may be a red unit pixel, and a portion corresponding to the green quantum dot may be a green unit pixel. Quantum dots may be printed using, for example, the inkjet method, but any method capable of printing a wavelength conversion material may also be used without departing from the scope or spirit of the present disclosure.

In order to protect the nanopore structure including quantum dots, the protective layer 370 may be formed on the first conductive semiconductor layer 340 to cover the light conversion layer 360. The protective layer 370 may be formed using a deposition process such as a chemical vapor deposition (CVD) process.

When using the manufacturing methods shown in FIGS. 14 to 17, the transfer substrate including LEDs of the first color, the second color, and the third color may be formed on one substrate. For example, the transfer substrate in which blue, red, and green LEDs are included in a single substrate may be formed. Therefore, even though three transfer processes composed of a first transfer process for transferring the blue LED substrate, a second transfer process for transferring the red LED substrate, and a third transfer process for transferring the green LED substrate are not performed, a substrate capable of emitting RGB light through only one transfer action can be formed, so that the entire transfer process can be simplified.

FIG. 18 is a cross-sectional view illustrating a display device manufactured according to the embodiments of the present invention. For a detailed description of the overlapping structure, refer to technology of the above embodiment.

The display device may include a first conductive semiconductor layer 340, a first conductive electrode 353 connected to the first conductive semiconductor layer 340, a second conductive semiconductor layer 350 disposed on the first conductive semiconductor layer 340, an active layer 351 disposed between the first conductive semiconductor layer and the second conductive semiconductor layer, a second conductive electrode 353 connected to the second conductive semiconductor layer, and a light conversion layer 360 formed on one surface of the first conductive semiconductor layer 340.

A detailed description of the first and second conductive semiconductor layers 340 and 352, the first and second electrodes 353, and the active layer 351 will be given in detail with reference to FIG. 10.

The light conversion layer 360 may display a color different from the color emitted by the semiconductor light emitting element. For example, when the semiconductor light emitting element is a blue semiconductor light emitting element, the light conversion layer may include the red or blue color.

The light conversion layer may be formed by the inkjet method. When inkjet printing is used, a material sprayed by a nozzle may be used by mixing a fluorescent material such as a phosphor with a material such as silicone. Since the light conversion layer is not printed on a portion corresponding to the blue unit pixel by the barrier, the light conversion layer corresponding to the red and green unit pixels may be printed.

As shown in FIG. 18, one surface of the light conversion layer 360 disposed to face one surface of the semiconductor light emitting element may be formed to be rougher than the other surface in contact with one surface of the semiconductor light emitting element. The surface of the light conversion layer 360 may include protrusions, so that the light conversion layer 360 may not be smooth. Alternatively, the thickness of the light conversion layer 360 may not be constant.

Embodiments of the present disclosure relate to a display device using semiconductor light emitting elements, and may also be applied to a display device using passive matrix (PM)-type semiconductor light emitting elements or to a display device using active matrix (AM)-type semiconductor light emitting elements.

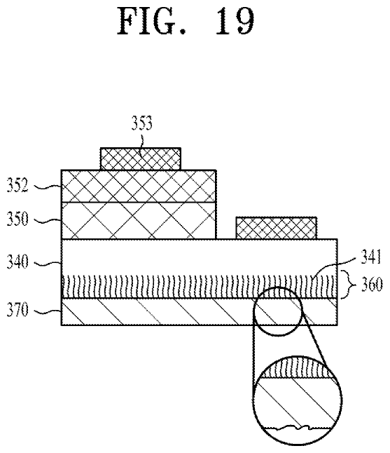

FIG. 19 is a cross-sectional view illustrating a display device manufactured according to the embodiments of the present disclosure. For a detailed description of the overlapping structure, refer to technology of the above embodiment.

The display device may include a first conductive semiconductor layer 340, a first conductive electrode 353 connected to the first conductive semiconductor layer, a second conductive semiconductor layer 350 disposed on the first conductive semiconductor layer 340, an active layer 351 disposed between the first conductive semiconductor layer and the second conductive semiconductor layer, a second conductive electrode 353 connected to the second conductive semiconductor layer, and a light conversion layer 360 formed in the first conductive semiconductor layer 340.

The first and second conductive semiconductor layers 340 and 352, the first and second electrodes 353, and the active layer 351 will be described in detail with reference to FIG. 12.

Referring to FIG. 19, one surface of the protective layer 370 disposed to face one surface of the semiconductor light emitting element may be formed to be rougher than the other surface in contact with one surface of the semiconductor light emitting element. A slope of a surface where the protective layer 370 and the first semiconductor layer 340 contact each other may be different from a slope of one surface of the semiconductor light emitting element. Furthermore, the surface of the protective layer 370 may include protrusions and may not be smooth. Alternatively, the thickness of the protective layer 370 may not be constant.

The light conversion layer 360 may be formed in the first conductive semiconductor layer 340 in a height direction from the surface of the first conductive semiconductor layer 340, and may be formed in the shape of a nanopore structure.

The nanopore structure may be formed by performing an electrochemical etching process on the surface of the first conductive semiconductor layer. The nanopore structure may be any structure having a nanoscale. For example, the nanopore shape may have various cross sections, such as a circular shape or a polygonal shape such as a square.

In order to protect the nanopore structure including quantum dots, a protective layer 370 may be formed on the first conductive semiconductor layer 340 to cover the light conversion layer 360. The protective layer 370 may be formed using a deposition process such as a chemical vapor deposition process. At this time, since the protective layer 370 is disposed on the nanopore structure, the protective layer 370 need not be disposed on the first semiconductor layer 340 where the nanopore structure is not formed.

As described above, the display device according to the embodiments of the present disclosure may be configured such that RGB light emitting elements are included in only one transfer substrate and the R, G, and B light emitting elements are transferred onto one transfer substrate through only one transfer process. As a result, since the number of transfer actions is reduced, the transfer efficiency can be improved, and the transfer process can be simplified.

Further, since the pixels adjacent to each other on the transfer substrate are arranged in a point-symmetrical manner, fabrication efficiency can be increased.

In addition, since the unit pixels emitting the same wavelength light are disposed adjacent to each other, the fabrication margin in the process of forming the light conversion layer can be increased.

In addition, since pixels are formed in a single chip structure and implemented so that color signals can be changed during operation, process change due to rotation of a chip is not caused during a self-assembly process of a single chip, thereby increasing process efficiency.

In addition, each pixel disposed on the transfer substrate may include two or more donors, so that the pixel can also be applied to any structure of a vertical light emitting element and a horizontal light emitting element.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments. The scope of protection of the present disclosure should be interpreted by the claims below, and all technical ideas within the scope equivalent thereto should be construed as being included in the scope of the present disclosure.

1. A transfer substrate comprising:
a first pixel and a the second pixel, the first pixel and the second pixel include a plurality of unit pixels;
wherein at least one of the plurality of unit pixels includes a semiconductor light emitting element of a first color;
remaining unit pixels among the plurality of unit pixels include the semiconductor light emitting element of the first color and a light conversion layer configured to convert the first color into a second or third color; and
the light conversion layer of the unit pixel disposed neighboring the second pixel among the plurality of unit pixels included in the first pixel is formed to have a same color as the light conversion layer of the unit pixel disposed neighboring the first pixel among the plurality of unit pixels included in the second pixel.

2. The transfer substrate according to claim 1, wherein:
the light conversion layer has a nanopore structure, and is included in the semiconductor light emitting element.

3. The transfer substrate according to claim 2, wherein:
the nanopore structure includes a wavelength conversion material.

4. The transfer substrate according to claim 3, wherein:
the wavelength conversion material includes a quantum dot (QD).

5. The transfer substrate according to claim 4, further comprising:
a protective layer formed on at least one side of the semiconductor light emitting element to cover the nanopore structure.

6. The transfer substrate according to claim 1, wherein:
pixel electrodes of the plurality of unit pixels included in the first pixel are formed to be point-symmetrical to pixel electrodes of the plurality of unit pixels included in the second pixel.

7. The transfer substrate according to claim 1, wherein:
pixel electrodes of the plurality of unit pixels included in the first pixel are formed to be line-symmetrical to pixel electrodes of the plurality of unit pixels included in the second pixel.

8. The transfer substrate according to claim 1, wherein:
the first pixel and the second pixel are integrated into a single chip.

9. The transfer substrate according to claim 1, wherein:
the first color is blue.

10. A method for manufacturing a display device comprising:
forming a plurality of semiconductor light emitting elements including a semiconductor light emitting element that corresponds to a unit pixel of a first color;
disposing a barrier on one surface of some of the semiconductor light emitting elements; and
forming a light conversion layer that converts the first color into a second or third color in a semiconductor light emitting element on which the barrier is not disposed among the semiconductor light emitting elements,
wherein forming the light conversion layer includes:
forming a first light coversion layer converting a color of at least one semiconductor light emitting element disposed neighboring a semiconductor light emitting element having a color to be converted into the second color, into the second color; and
forming a second light coversion layer converting a color of at least one semiconductor light emitting element disposed neighboring a semiconductor light emitting element having a color to be converted into the third color, into the third color.

11. The method according to claim 10, wherein forming the light conversion layer includes:
forming a nanopore structure; and
injecting a wavelength conversion material into the nanopore structure.

12. The method according to claim 11, further comprising:
forming a protective layer on at least one side of the semiconductor light emitting element to cover the nanopore structure.

13. A display device comprising:
a semiconductor light emitting element configured to display light of a first color;
a light conversion layer disposed inward from one surface of the semiconductor light emitting element, and formed in a nanopore structure to convert the first color into a second color different from the first color; and
a protective layer stacked on one surface of the semiconductor light emitting element to cover the light conversion layer,
wherein
the protective layer is configured in a manner that one surface thereof facing one surface of the semiconductor light emitting element is formed to be rougher than the outer surface contacting one surface of the semiconductor light emitting element.

14. The method according to claim 10, wherein the wavelength conversion material includes a quantum dot (QD).

15. The method according to claim 14, wherein the quantum dot is impregnated into the nanopore structure using an inkjet method.

16. The method according to claim 10, wherein the barrier is located at a center of the plurality of semiconductor light emitting elements among a group of three semiconductor light emitting elements.

17. The method according to claim 16, wherein the group of three semiconductor light emitting elements forms a first pixel and a second pixel.

18. The method according to claim 17, wherein the light conversion layer of the unit pixel disposed neighboring the second pixel among the plurality of unit pixels included in the first pixel is formed to have a same color as the light conversion layer of the unit pixel disposed neighboring the first pixel among the plurality of unit pixels included in the second pixel.

19. The method according to claim 17, wherein:
pixel electrodes of the plurality of unit pixels included in the first pixel are formed to be point-symmetrical to pixel electrodes of the plurality of unit pixels included in the second pixel.

20. The method according to claim 17, wherein:
pixel electrodes of the plurality of unit pixels included in the first pixel are formed to be line-symmetrical to pixel electrodes of the plurality of unit pixels included in the second pixel.
